(19) United States
(12) Patent Application Publication
(10) Pub. No.: US 2017/0111045 A1
(43) Pub. Date: Apr. 20, 2017

(54) PRESSURE SENSITIVE ILLUMINATION SYSTEM

(71) Applicant: TK Holdings Inc., Auburn Hill, MI (US)

(72) Inventors: Jason Lisseman, Shelby Township, MI (US); David Andrews, Ortonville, MI (US)

(21) Appl. No.: 15/391,013

(22) Filed: Dec. 27, 2016

Related U.S. Application Data
(62) Division of application No. 13/673,463, filed on Nov. 9, 2012.
(60) Provisional application No. 61/558,245, filed on Nov. 10, 2011.

(51) Int. Cl. H03K 17/96; H05B 37/02; G06F 3/041

(52) U.S. Cl. CPC H03K 17/9638; G06F 3/0414; H05B 37/0227; H03K 17/9625; G06F 3/016

(57) ABSTRACT

Implementations of the present disclosure provide a human interface including a light emitter and a pressure sensitive material. The pressure sensitive material has electrical properties configured to vary in relation to an amount of pressure applied thereto. The light emitter is coupled to the pressure sensitive material, wherein variation of the electrical properties of the pressure sensitive material causes variation of at least one illumination characteristic. Advantageously, the pressure sensitive material provides an additional control component allowing bundling of controls in a simpler interface. At the same time, operation of the human interface in low-light or distracted environments is facilitated and rendered more intuitive by incorporation of the light emitter into its operation.

### CROSS-REFERENCE TO RELATED APPLICATIONS

This application is a Divisional of U.S. Non-Provisional patent application Ser. No. 13/673,463 filed Nov. 9, 2012, which claims priority to U.S. Provisional Patent Application No. 61/558,245 filed Nov. 10, 2011, the disclosures of which are incorporated herein in their entireties by reference.

### BACKGROUND

The present disclosure relates generally to the field of human interfaces. More specifically, it relates to human interfaces for controlling systems in a distracted or low light environment using light as a feedback indicator.

Unlike standard desktop computers, control systems for real-world physical constructs, like automobiles, planes or heavy equipment, do not afford an operator the ability to devote full attention to manipulation of the controls. For example, in an automobile a driver should avoid diverting direct visual attention from the road in order to operate automotive system controls, such as audio system controls.

Standard switches and other controls are most often simple, single degree-of-freedom switches, levers and dials that do not require much diversion of attention to activate. For example, many switches are on/off switches that toggle between two positions with a click that communication activation to the driver without direct visual attention.

More complex control systems, however, often are not well-received by drivers as it is difficult to devote full attention to these control systems. However, over time the numbers of automobile systems and features have climbed precipitously, resulting in oftentimes cluttered cockpits of simple switches. Although each switch is simple to operate, the sheer number of switches begins to counteract this simplicity.

It is desirable, therefore, to have control systems that afford clear, intuitive feedback in situations where an operator cannot afford to devote full attention to the controls and/or the controls are being operated in low light environments.

### SUMMARY

Implementations of the present disclosure overcome the problems of the prior art by providing a human interface including a light emitter and a pressure sensitive material. The pressure sensitive material has electrical properties configured to vary in relation to an amount of pressure applied thereto. The light emitter is coupled to the pressure sensitive material, wherein variation of the electrical properties of the pressure sensitive material causes variation of at least one illumination characteristic. Advantageously, the pressure sensitive material provides an additional control component beyond just positioning, allowing bundling of controls in a simpler interface. At the same time, operation of the human interface in low-light or distracted environments is facilitated and rendered more intuitive by incorporation of the light emitter into its operation.

The illumination characteristic, for example, may include an intensity, visibility or position of the illumination. Other illumination characteristics include color, shape, intensity or graphics. The illumination characteristic may also be dynamic, such as a rate of pulsing intensity of the illumination. For example, the pulsing could speed up with increased pressure on the pressure sensitive material.

The pressure sensitive material may be positioned on the light emitter. Also, the pressure sensitive material may be configured to at least partially allow passage of light from the light emitter through itself to form the illumination characteristic. For example, the pressure sensitive material may define one or more openings configured to allow passage of light from the light emitter. The openings may be arranged in a pattern, such as in an array. The openings may also be covered or filled by windows which support or include graphical elements.

Also included in the human interface may be a processor. The processor may be configured to determine a position of the amount of pressure on the pressure sensitive material based on the electrical properties of the pressure sensitive material. The processor may be further configured to determine when a proximal opening of an array of openings is in proximity to the position and to cause the light emitter to emit light through the proximal opening.

Further, the processor may be configured to determine a path of the amount of pressure and when proximal openings are in proximity to the path, and to cause the light emitter to emit light through the proximal openings to form a light path.

The human interface may also include a force concentrator positioned on the pressure sensitive material. The force concentrator may be translucent or transparent. For example, the force concentrator may also be a light guide. The human interface may further include a reaction surface, wherein the pressure sensitive surface is positioned between the reaction surface and the light guide. An opening in the reaction surface may be configured to hold the light emitter.

Also included in the human interface may be a cover configured to deflect under normal finger pressure. The light guide may be positioned between the cover and the pressure sensitive material. The cover may include a graphic configured to be revealed by light from the light emitter so as to at least partially vary the illumination characteristic.

The human interface may have a compact or thin arrangement facilitated by the cover, light guide and pressure sensitive material being formed as sheets.

The light emitter may include one or more of an LCD array, an LED back-lit LCD array, a monochromatic transparent display or a backlit display. The light emitter may be configured as a thin sheet that is capable of selectively positioned illumination. Also, the thin sheet may be configured for high-intensity light emission.

The thin sheet may include a mask layer and a light emitter layer positioned between the mask layer and the pressure sensitive material. The human interface may also include a light guide wherein the thin sheet light emitter is positioned between the light guide and the pressure sensitive material. The mask layer may be a monochromatic transparent display and the light emitter layer may be a high intensity light source.

The thin sheet light emitter may also include an active matrix mask or include an active lighting matrix.

If a light guide is used in the human interface, the thin sheet light emitter may be positioned between the light guide and the pressure sensitive material. Both the light guide and the pressure sensitive material may be configured as sheets and a cover sheet may be used on the light guide. The cover sheet may include a structural skeleton with a printed graphic. For example, the printed graphic could be created with in-mold labeling (IML) or in mold decoration (IMD).

Variations of the cover sheet are also possible. For example, the cover sheet may be positioned on the pressure sensitive material or on the light emitter and be configured to facilitate transmission of the amount of pressure to the pressure sensitive material in a “semi-lossless transfer” of the force.

Another option is to include haptic features on the cover sheet. For example, the cover sheet could include one or more of an emboss (raised impressions), deboss (indentations or depressions), Braille or recesses to facilitate use of the pressure sensitive material when in low light or distracted environments, such as a motor vehicle.

The cover sheet may be in layers, such as a structural layer bonded to a top silicone layer bonded to create the haptic features. Other materials may be used for the cover for an attractive appearance, such as leather, wood, jade, plastics, metals, ceramics, fabrics and textiles.

The light emitter may include a spatial component, such as a length or width. A processor associated with the light emitter and pressure sensitive material may be configured to cause the light emitter to increase illumination along the spatial component in proportion to the amount of pressure. The spatial component may include (or be divided into) a plurality of zones extending in the direction of the spatial component.

The pressure sensitive material may include a spatial component wherein the illumination characteristic is a graphical characteristic. For example, the graphical characteristic may be an alphanumeric sequence and a processor may be configured to cause the alphanumeric sequence to increase or decrease in proportion to the amount of pressure applied to the pressure sensitive material.

These and other features and advantages of the implementations of the present disclosure will become more readily apparent to those skilled in the art upon consideration of the following detailed description and accompanying drawings, which describe both the preferred and alternative implementations of the present disclosure.

### BRIEF DESCRIPTION OF THE DRAWINGS

FIG. 1 is a schematic of a human interface system;

FIG. 2 is a cross-sectional view of an illuminated sensor;

FIG. 3 is a perspective view of a sensor material and light emitter from the illuminated sensor of FIG. 2;

FIG. 4 is a cross-sectional view of an illuminated sensor with a flat light layer;

FIG. 5 is a perspective view of a sensor material and flat light layer of FIG. 4;

FIGS. 6-8 are perspective views of sensor material sheets with openings for light emitters;

FIG. 9 is a schematic of an illuminated pressure sensor with an active lighting matrix;

FIG. 10 is a schematic of functional shapes defined in one or more pressure sensitive layers;

FIG. 11 shows an exploded view of an illuminated sensor;

FIG. 12 is a cross-sectional view of another illuminated sensor with an active matrix;

FIGS. 13-15 are perspective views of active matrix displays of the illuminated sensor of FIG. 12;

FIG. 16 is a cross-sectional view of an illuminated sensor with haptic features on a cover;

FIGS. 17-20 are cross-sectional views of sensor covers with various haptic features;

FIGS. 21-23 are schematics of strip sensors with associated strip lighting displays;

FIGS. 24 and 25 are schematics of strip lighting displays overlaid on strip sensors;

FIGS. 26-29 are strip sensors with associated displays of illuminated indicia;

FIG. 30 is a cross-section of a pressure sensitive system; and

FIG. 31 is a graph of theoretical resistance characteristics of a pressure sensor using a pressure sensitive material.

### DETAILED DESCRIPTION

Implementations of the present disclosure now will be described more fully hereinafter. Indeed, these implementations can be embodied in many different forms and should not be construed as limited to the implementations set forth herein; rather, these implementations are provided so that this disclosure will satisfy applicable legal requirements. As used in the specification, and in the appended claims, the singular forms “a”, “an”, “the”, include plural referents unless the context clearly dictates otherwise. The term “comprising” and variations thereof as used herein is used synonymously with the term “including” and variations thereof and are open, non-limiting terms.

Generally, a human interface 10, including a light emitter 24 and a pressure sensitive material 16, is disclosed. The pressure sensitive material 16 has electrical properties configured to vary in relation to an amount of pressure applied thereto. The light emitter 24 is coupled to the pressure sensitive material, wherein variation of the electrical properties of the pressure sensitive material causes variation of at least one illumination characteristic. Advantageously, the pressure sensitive material 16 provides an additional control component allowing bundling of controls in a simpler interface. At the same time, operation of the human interface 10 in low-light or distracted environments is facilitated and rendered more intuitive by incorporation of the light emitter 24 into its operation.

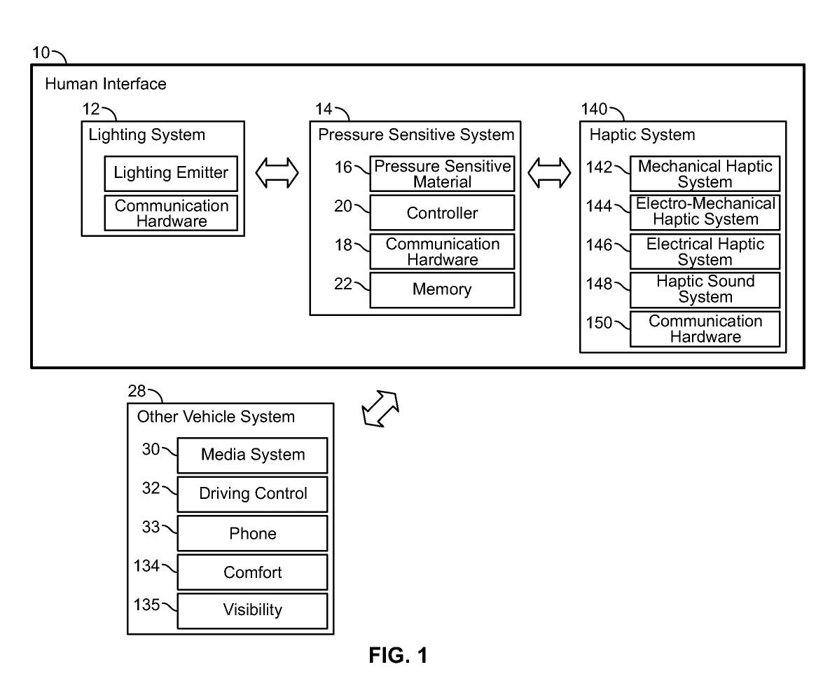

FIG. 1 schematically depicts one example of the human interface 10 including a lighting system 12 and a pressure sensitive system 14 and a haptic system 140 that can be used for controlling other vehicle systems 28. The pressure sensitive system 14 may include one or more of software, hardware and firmware, for example, that operate as a pressure sensitive material 16, communication hardware 18, a controller 20 and memory 22. The lighting system 12 may include, for example, a light emitter 24 and its own communication hardware 26. The human interface 10 may also interact with the other vehicle systems 28, such as by controlling or monitoring the other vehicle systems 28. The other vehicle systems 28 may include, for instance, a media system 30, a driving control system 32, a phone system 33, a comfort system 134 and a visibility system 135. The haptic system 140 may include a mechanical haptic system 142, an electro-mechanical haptic system 144, an electrical haptic system 146, a haptic sound system 148 and communication hardware 150.

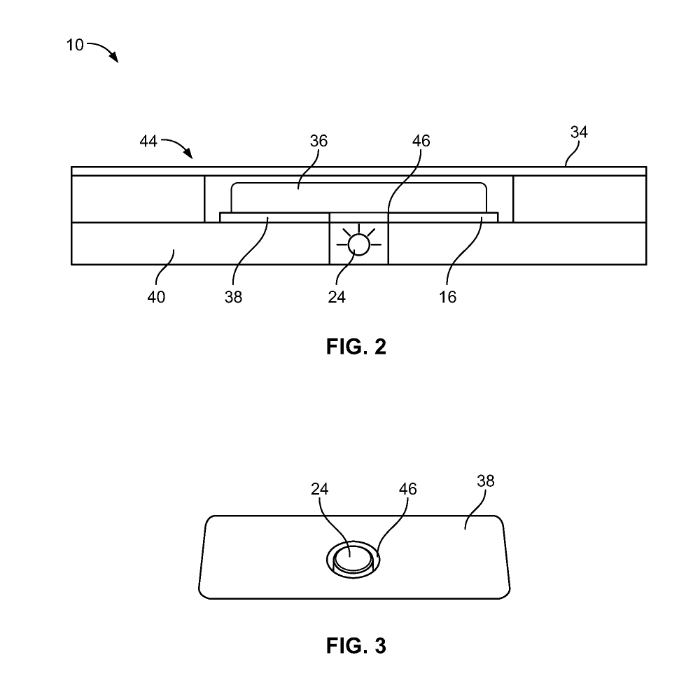

As shown in FIG. 2, the human interface 10 may include, in another example, an illuminated sensor 44 including a cover 34, a light guide (and/or force concentrator) 36, a pressure sensitive layer 38, a reaction surface 40 and the light emitter 24. The cover 34 is layered onto a support layer 42 that rests on the reaction surface 40. The support layer 42 has an opening that houses the light guide 36 and the pressure sensitive layer 38.

The cover 34 may be, for example, a molded cover with in mold decoration (IMD) or in mold labeling (IML) to provide indicia or haptic contours to fit the control application of the human interface 10. The cover 34 may act as, or include, a structural skeleton and may further include printed graphics on its top surface or as an underside film. The graphics may be configured to operate with the light emitter 24, such as by having a hidden until lit graphic or with a plain hidden until lit surface.

The cover 34 may have a thickness and/or material properties to enable deflection under pressure from the user. For example, the cover may be configured to deflect under finger pressure to make contact with the underlying light guide 36.

The light guide 32, as shown in FIG. 2, is positioned under the cover 34 and may include a gap therebetween to afford a distance to be overcome to exert pressure on the underlying light guide. This gap may also help with the design tolerance stack of multiple components. The light guide 32 is positioned above and rests upon the pressure sensitive layer 38. The light guide 32 has a width configured to fit within the opening defined in the support layer 42 and is slightly narrower than the underlying pressure sensitive layer 38.

The light guide 32 may be a clear, transparent or translucent sheet of material that facilitates or permits passage of light emitted by the light emitter 24. The light guide may be configured to operate by total internal reflection and may be constructed, for example, of optical grade materials such as acrylic resin, polycarbonate, epoxies and/or glass. The light guide 36 may be used to collect and direct light to backlight a display. Also, the light guide could be configured to increase perpendicular light passage when deflected under pressure. In this configuration, the distortion from deflection can increase perpendicular light flow by disrupting the path of the light flow.

Rather than being positioned under the cover 34, the light guide 32 may extend through a gap, window or other opening defined in the cover. (The cover 34 in this instance may be more of a decorative surface.) The light guide 32 may be clear or coated with some translucent material, such as a translucent chrome coating or ink or paint, or could be covered by a thin film, such as an IML film. The light guide 32 or thin film could also have rear side printing using, for example, black panel technology or decorative features such as indicia (markings, designs, patterns or colors) and could also be flood filled with a clear translucent material such as polyurethane. The thin film could also be a cap for a clear plastic or silicone light guide. In any case, contact would be directly with the light guide 32 rather than with the cover 34 itself.

The term “sheet” as used herein may refer to a structure with a thickness that is a fraction of its remaining two linear dimensions. It need not be a very small thickness with flat surfaces, but could instead be a layer with two relatively opposing surfaces between edges of any general shape between which is defined a thickness, or range of thicknesses that is 1/10, ¼, ⅓ or ½ of a width or length of the opposed surfaces, for example. Also, the opposing surfaces do not need to be flat or regular in finish, nor precisely parallel from each other. The term “thin sheet” is used herein to define a sheet with thickness of less than 1/10 a dimension of one of the opposing surfaces.

As an additional function, the light guide 32 may also be configured to act as a force concentrator by having stiffness and other mechanical properties which facilitate registration of the pressure applied to the cover 34 through to the underlying pressure sensitive layer 38. The light guide 32 may also have multiple mechanical properties configured to tune the mechanical responsiveness of the illuminated sensor 44. The light guide may also include geometric features to focus force onto the sensing zone, or to partially offset forces onto a non-sensing zone. For example, these geometric features could include surface area adaptations, collapsing portions or end stops that control the mechanical force deflection characteristics proscribed by many customer specifications. This includes, for example, silicone dome cap applications.

The pressure sensitive layer 38 is relatively thin compared to the light guide 36 and extends between the light guide 36 and the reaction surface 40. The pressure sensitive layer 38 is configured to act as an x-y position coordinate (or just x or y) and z pressure coordinate sensor, such as the sensors employed in commonly owned U.S. patent application Ser. No. 13/076,226 entitled “Steering Wheel Sensors” and filed on Mar. 30, 2011, which is incorporated herein in its entirety by reference. Additional details about the operation of a pressure sensitive layer in x, y and z space may be found in PCT Patent Application Publication No. WO 2010/109186 entitled “Sensor” and published on Sep. 30, 2010, which is incorporated herein in its entirety by reference. The pressure sensitive layer 38 may have a range of shapes depending upon the intended application, such as the rectangular shape shown in FIG. 3. The rectangular shape facilitates use of full x-y position coordinates. Or, for example, the pressure sensitive layer 38 may have an elongate or strip shape for single-axis translation or may have a circular shape for rotational coordinate registration.

Defined in one or more locations of the pressure sensitive layer 38 may be one or more windows or openings 46 for a “through sensor” lighting configuration, as shown in FIGS. 2 and 3. For example, the opening 46 may be centrally located on the rectangular pressure sensitive layer 38 and have a circular shape configured to provide full exposure to the underlying light emitter 24. The opening may be a full thickness opening (as illustrated) or may be only a partial thickness opening or hole or may instead by defined or filled by a clear or transparent or translucent material (such as the light guide material described above) so as to establish some visible light transmission or communication through the light guide 36.

The reaction surface 40 is a bottom layer that supports the remaining layers and is configured to have a relatively stiff structure so as to resist the pressure of the applied force. Also, the reaction surface may define a lighting receptacle configured to receive and/or house one or more light emitters 24. The intervening support layer 42 may have similarly stiff properties if desired for support of the cover 34 and to facilitate function as a spacer to provide secure housing for the light guide 36 and pressure sensitive layer 38.

The light emitter 24 may be any of a range of light producing devices or materials, including light-emitting diodes (LEDs), light bulbs or more remote lighting conducted into a functional position, such as through fiber optics extended under the pressure sensitive layer 38 and terminating under the pressure sensor opening 46. Also, groups of smaller light emitters may act as a single light emitter when used in combination.

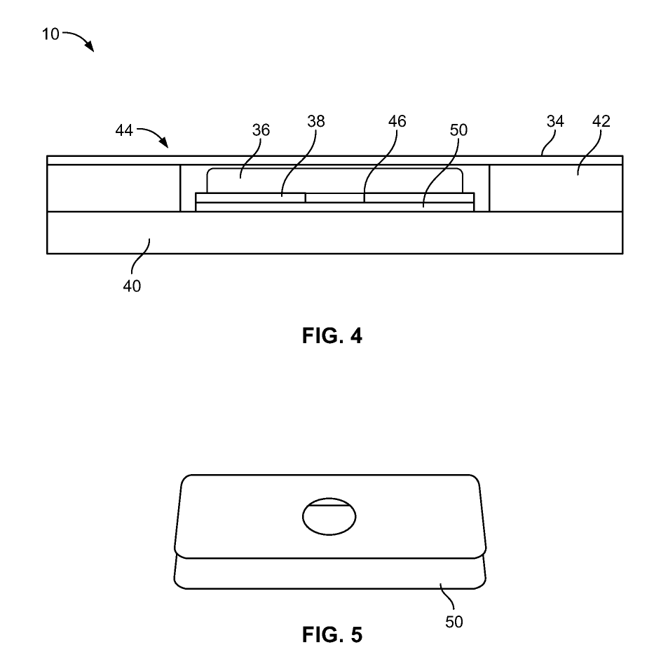

FIGS. 4 and 5 show an illuminated sensor 44 that includes a flat light source or layer 50 positioned between the pressure sensitive layer 38 and the reaction surface 40. The layer may be, for example, a liquid crystal (LCD) display layer or flat light guide over an LED backlight or an organic electro-luminescence layer (OLED) that is configured to emit light across a relatively thin, flat surface. Regardless, the layer emits light through the one or more pressure sensor openings 46. An advantage of the use of an illuminated layer is that it facilitates a wider range of shapes, locations or combinations of the openings 46 than the particular locations and light emission ranges of individual light bulbs or diodes.

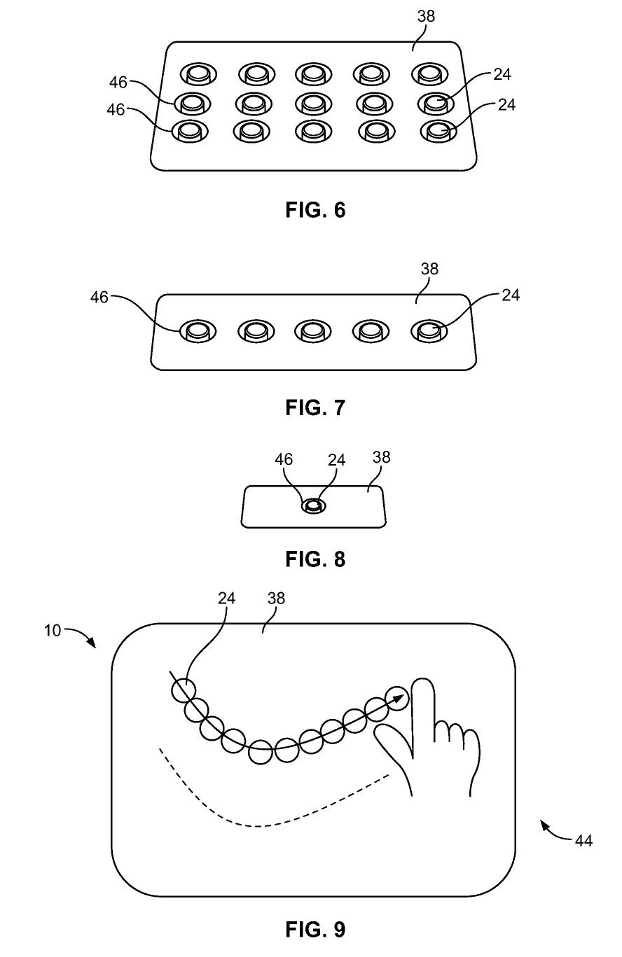

FIG. 6 shows another pressure sensitive layer 38 having a rectangular shape but with a plurality of the pressure sensor openings 46 arranged in a 3×5 rectangular array to correspond to a 3×5 rectangular array of underlying light emitters 24. The light emitters could also be supplanted by the flat light source 50 shown in FIGS. 4 and 5 with the array defined by the openings 46. FIGS. 7 and 8 show pressure sensitive layers 38 with strip configurations and one (FIG. 8) or multiple (such as five) openings 46 with corresponding light emitters 24.

Lighting could also be provided by an active lighting matrix, such as multiple individually addressable single light sources or pixel level illumination. FIG. 9, for example, shows an active lighting matrix wherein communication between the pressure sensitive system 14 and the lighting system 12 activates a light trail or path corresponding to the pressure and x-y position of a swipe or touch trail. For example, the lighting system 12 may be configured to determine, such as by a processor, a path of pressure applied to the pressure sensitive layer 38 and to determine when selected openings 46 are in proximity to the path and to cause light emission through the selected openings by underlying light emitters 24. As noted above, additional details about the operation of a pressure sensitive layer in x, y and z space may be found in PCT Patent Application Publication No. WO 2010/109186 entitled “Sensor” and published on Sep. 30, 2010, which is incorporated herein in its entirety by reference.

Advantageously, increased pressure could be used to create variations in the characteristics of the illumination, such as increased lighting intensity, changes in shape or color. A light path width, for example, could be wider or could have a variable rate pulsing characteristic (e.g., faster pulsing) under increased pressure. Or, a light touch pressure could range through the visible color spectrum from blue to red in proportion to the increased pressure.

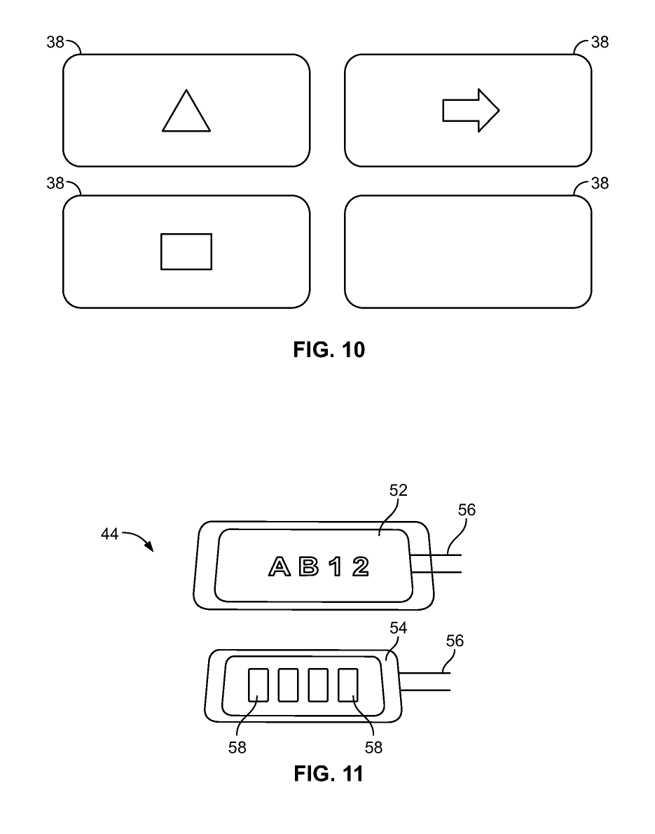

FIG. 10 shows variations in openings 46 in the pressure sensitive layer 38 that have functional shapes facilitating interpretation by the user of the purpose of the button, such as a triangle, arrow, square or alphanumeric sequence. Shapes and indicia could be modified to express the underlying function of the illuminated sensor 44.

To further aid the user (e.g., automobile driver or passenger) it is possible that a range of illumination characteristics, such as colored lighting, can be used on the illuminated sensor 44. For example, the illuminated sensor 44 may include a phone symbol that is an unlit, hidden phone symbol when the phone is not connected, a white phone symbol when the phone is connected and ready to call, a green pulsating phone symbol when a phone call is incoming (or outgoing) but not answered, a red phone symbol for calls in progress (pushing the sensor 44 ends the call) or a red pulsating phone symbol when the call is ending.

FIG. 11 shows an exploded view of another alternative wherein the pressure sensitive layer 38 includes an upper electrode 52, a lower electrode 54 and a sheet of pressure sensitive material 16 extending therebetween. The upper and lower electrodes 52, 54 include signal lines or leads 56 (e.g., communication hardware 18) for electrical communication with the controller 20. The upper electrode 52 (or lower electrode) may define a mask structure that includes openings, such as indicia-shaped openings, that provide visibility through to windows 58 defined in the sheet of pressure sensitive material 16 positioned thereunder. The windows 58 may also provide visibility through to a flat light layer 50 positioned between the lower electrode 54 and the pressure sensitive material 16.

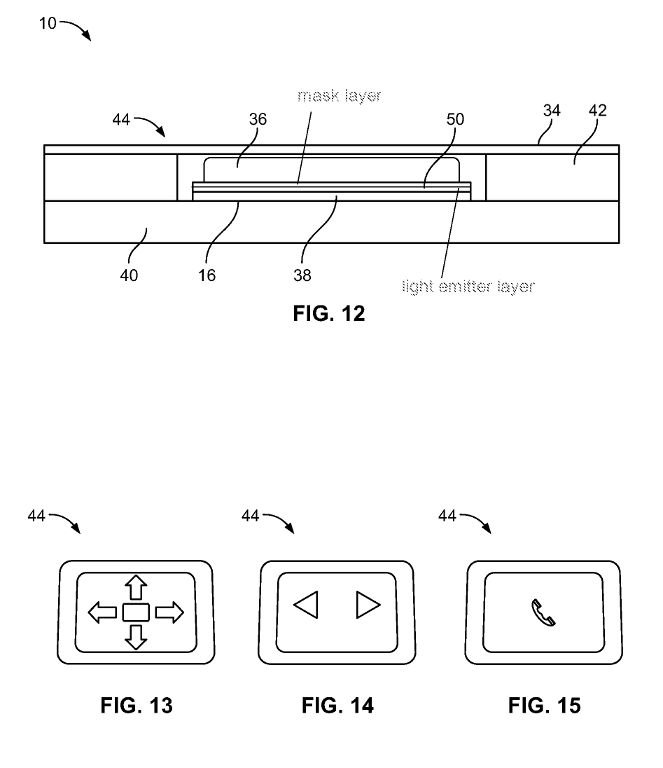

FIG. 12 shows an illuminated sensor 44 wherein the flat light layer 50 is on top of the pressure sensitive layer 38 and under the light guide 36, advantageously negating the need for openings in the pressure sensitive layer 38. For example, the flat light layer 50 may include a light source with an active matrix mask or an active lighting matrix. The mask, for example, may be a thin film monochromatic display with a high-intensity light source positioned therebelow.

The combination of light source and mask/matrix could enable a variable output display along with light emission and pressure sensing in the same space wherein different images could be presented to facilitate operation by the user. FIGS. 13-15 show examples of a variable display that could be generated by the illuminated sensor 44 of FIG. 13, such as an ordinal arrow set with center selector button (FIG. 13), paired left-and-right arrows (FIG. 14) or a phone (FIG. 15). The user could then press on the illumination characteristic and have the location and amount of pressure registered by the underlying pressure sensitive layer.

Conversely, the lighting system 12 could be positioned remote from the pressure sensitive system 14. For example, the lighting system could be a central styled feature surrounded by pressure sensors. The lighting system 12 could serve to demonstrate that any one or a particular combination of the pressure sensors or their respective functions have been activiated.

FIGS. 17-20 show covers 34 that include an additional over-molded layer 60 that have passive haptic characteristics or features, e.g., are part of the haptic system 140 shown in FIG. 1. The over-molded layer 60 could be separately formed or the haptic aspects (e.g., mechanical or electro-mechanical haptic systems 142, 144) may be configured on or supported an integrally formed cover 34. Similar to the cover 34, the over-molded layer 60 may be molded or IMD or IML constructed. The electrical haptic system 146 may generate electrical based feedback such as vibration or with sound (e.g., the haptic sound system 148). All of these haptic systems can communicate with the pressure sensitive system 14 and lighting system 12 via communication hardware 150.

The haptic features may include embossing, debossing, Braille or various recesses. FIG. 17, for example, may include a recess 62 and a pair of posts 64 flanking the recess. This structure would guide the user working in distracted or low-light conditions toward the functional pressure sensitive locations of the illuminated sensor 44 at the recess 62.

FIG. 18, for example, shows ledges 66 that drop off from the front surface of the over-molded layer 60 with a further taper to the recess 62. FIG. 19, for example, shows a pair of rounded features 68 flanking the recess 62. FIG. 20, for example, shows negative space used as haptic features in the form of a pair of troughs 70 that bracket the recess 62.

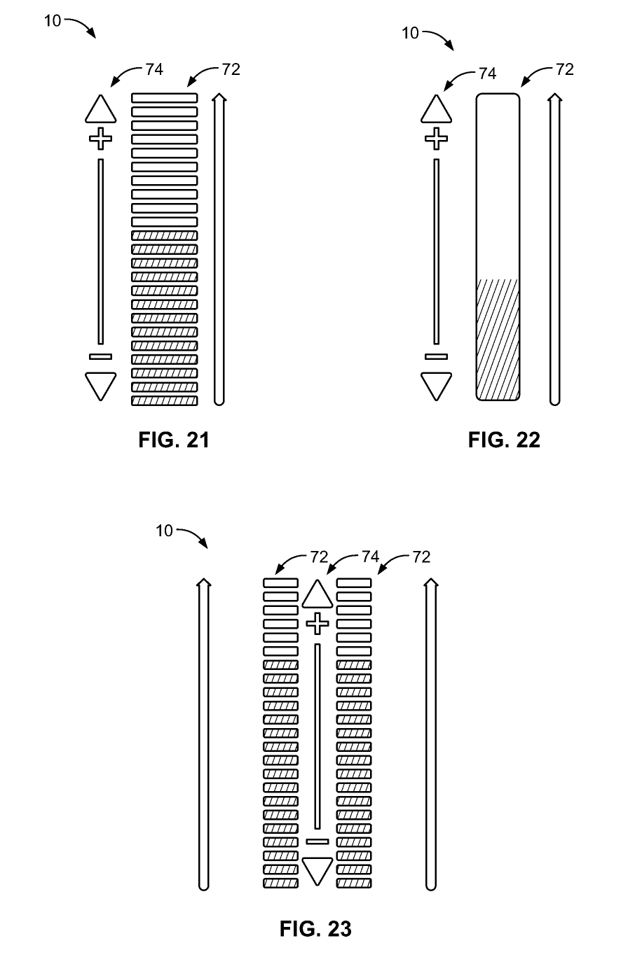

FIGS. 21-29 show lighting systems 12 that can be used with pressure sensitive systems 14 in the human interface 10. FIG. 21, for example, shows a lighting system 12 that includes zoned lighting display 72 with a strip sensor 74. The zoned lighting display includes a plurality of discrete zones in the form of rectangular strips arranged in a parallel array. Adjacent the zoned lighting display 72 and extending along its length is the strip sensor 74 that includes a plus end and a minus end. The plus/minus indicia may correspond to the impact on a controlled system, such as increasing the volume of the sound system 30 in the plus direction and decreasing it in the minus direction via the controller 20.

In addition, the parallel arrangement of the lighting display 72 and strip sensor 74 give them a common linear spatial component. (The arrow indicates the direction of the linear spatial component which is the direction of fill for the zones with the increase in the measured parameter.) For example, controller 20 may include a processor configured to determine the position of the amount of pressure applied to the material 16 and to map the spatial component of the pressure sensitive material onto the light emission spatial component. Alternatively, or in addition, the spatial component of the light emitter 24 could correspond to an amount of applied pressure or some other parameter measured by the strip sensor 74.

The strip sensor 74 may itself be divided into a plurality of zones with individualized zones of pressure sensitive material 16 arranged with a size and orientation corresponding to the zones of the zoned lighting display 72. Zones of the lighting display 72 may be then energized to emit light in correspondence with the application of pressure to the zones of the strip sensor 74.

The strip sensor 74 may be an over-molding 60 of indicia on the pressure sensitive layer 38 itself, such as in the configurations of FIGS. 17-20, or may be indicia created by an active matrix or mask, such as in the configurations of FIGS. 12-15. Thus the gradient indicator 74 may be subject to a sliding finger contact with the zones of the zoned lighting display 72 illuminated progressively to correspond to the finger position.

FIGS. 22 and 23 show variations of adjacent zoned lighting display 72 and strip sensor 74 configurations. FIG. 22 shows a lighting display 72 that mimics analog display of a continuous light bar that increases or decreases in proportion to the measured parameter. FIG. 23 shows dual zoned lighting displays 72 extending in parallel with the strip sensor 74.

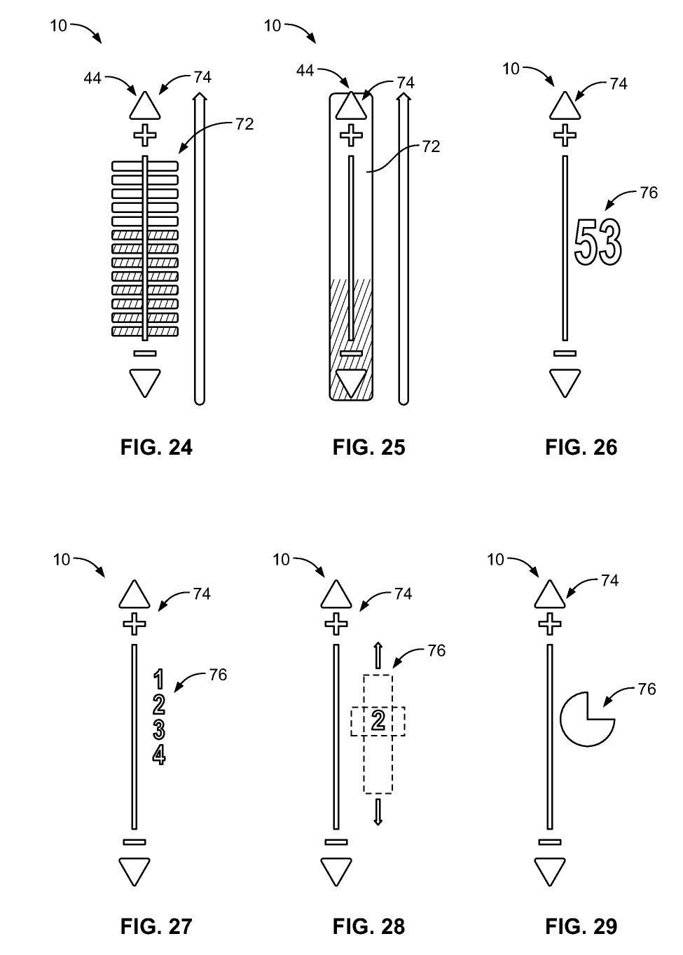

FIGS. 24 and 25 show overlay of the strip sensor 74 on the zoned lighting display 72 that may be formed, for example, by having an active matrix or mask as part of the sensor to create both the plus/minus indicia and the zoned lighting both through the surface of the illuminated sensor 44, such as in the configurations of FIGS. 12-15. Or, in another example, the zoned lighting display 72 may be created by windows 58 in the pressure sensitive material 16 overlaid with a structure of the cover 34 to form the plus/minus indicia.

FIGS. 26-29 show the use of illuminated indicia 76 to characterize the activation of the strip sensor 74. FIG. 26 shows the strip sensor 74 positioned next to the illuminated indicia 76 that displays a range of numeric indicia in proportion to some parameter (such as position and/or pressure) sensed by the strip sensor. FIG. 27 shows the illuminated indicia 76 as having a progressive aspect wherein the numbers are arranged to light sequentially with sensing of the parameter by the strip sensor 74. FIG. 28 is similar to FIG. 27, except that the non-illuminated numbers are invisible.

FIG. 29 shows another variation wherein the illuminated indicia 76 include a progressive-fill pie chart that increases in fill with the sensed parameter. The human interface 10 may use a range of pressure-sensitive materials in the pressure sensitive system 12. Generally, however, the pressure sensitive material outputs a variable resistance (or other electrical characteristic) based on the amount or type (e.g., gesture, press, swipe, prolonged touch, short tap, etc.) of pressure that is applied to the material. In some examples, the pressure sensitive material may be a quantum tunneling composite, while in other examples, any other pressure sensitive material capable of having variable electrical characteristics may be used.

The pressure sensitive material may be configured to change resistance or conductive/electrical characteristics in response to force or pressure acting thereupon. More particularly, the pressure sensitive material behaves substantially as an isolator when no force or pressure is present and decreases in resistance as more force or pressure is present. Between low and high forces, the pressure sensitive material responds to force or pressure in a predictable manner, decreasing in resistance with increasing force.

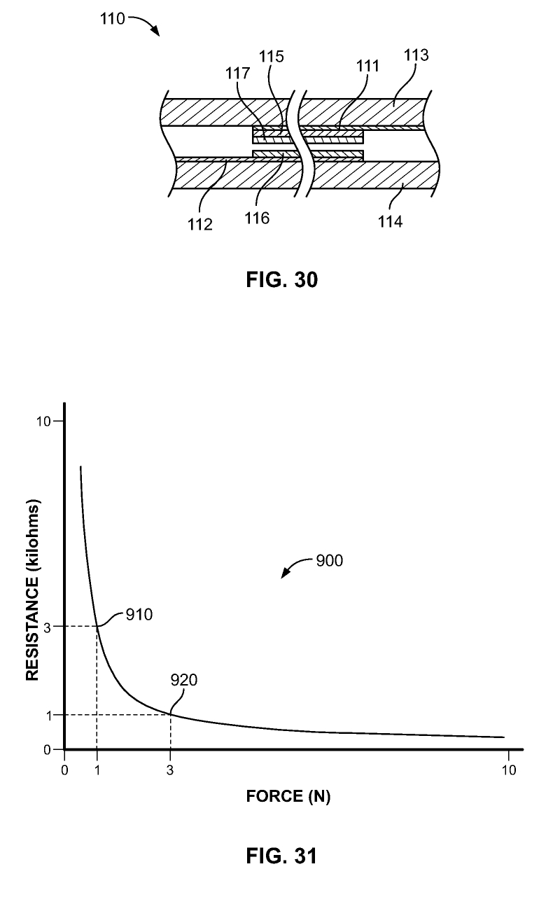

For example, as shown in FIG. 30, a pressure sensitive sensor 110 may include sheets of carrier material 113, 114, conductors 111, 112, electrodes 115, 116, and a pressure sensitive material 117 configured in a generally symmetric, layered relationship (e.g., a carrier sheet, conductor, and electrode disposed on each side of the pressure sensitive material). The carrier sheets 113, 114, conductors 111, 112, electrodes 115, 116, and pressure sensitive material 117 may be selectively configured to change conductive or electrical characteristics of the sensors 110 according to the forces expected during a dynamic application of pressure.

The pressure sensitive material 117 may, for example, be a carbon nanotube conductive polymer. The pressure sensitive material 117 is applied to one of the pair of electrodes 115, 116 by a printing process, such as two- or three-dimensional ink jet or screen printing, vapor deposition, or conventional printed circuit techniques, such etching, photo-engraving, or milling. As pressure sensitive materials 117 with smaller particle sizes are used, such as that of grapheme or a grapheme conductive polymer, the pressure sensitive material 117 may also be applied through conventional printed circuit techniques, such as vapor deposition. According to other examples, the pressure sensitive material may be a silicene polymer material doped with a conductor, such as silver or copper.

According to other examples, the pressure sensitive material is a quantum tunneling composite (QTC), which is a variable resistance pressure sensitive material that employs Fowler-Nordheim tunneling. QTC is a material commercially made by Peratech (www.peratech.com), of Brompton-on-Swale, UK. The QTC material in the sensors 110 may act as an insulator when zero pressure or zero force is applied, since the conductive particles may be too far apart to conduct, but as pressure (or force) is applied, the conductive particles move closer to other conductive particles, so that electrons can pass through the insulator layer changing the insulator layer changing the resistance of the sensor 110. Thus, the resistance of the QTC in the sensors 110 is a function of the force or pressure acting upon the sensor 110.

The carrier sheets 113, 114 are coupled together to form the sensor sheet 100 after the conductors 111, 112, electrodes 115, 116, and pressure sensitive material 117 are deposited thereon. The carrier sheets 113 may, for example, be laminated together, such that the conductors 111, 112, electrodes 115, 116, and pressure sensitive material 117 are in proper alignment. The lamination process may for example be a conventional process using heat and pressure. Adhesives may also be used. The total thickness of the sensor sheet 100 and/or sensors 110 may be approximately 120 microns. According to other examples, the carrier sheets 113, 114 may, for example, be coupled together in other manners (e.g., laminating without heat or pressure). Further, the sensor sheet 100 and/or sensors 110 may have a different total thickness (e.g., greater than or equal to approximately 70 microns).

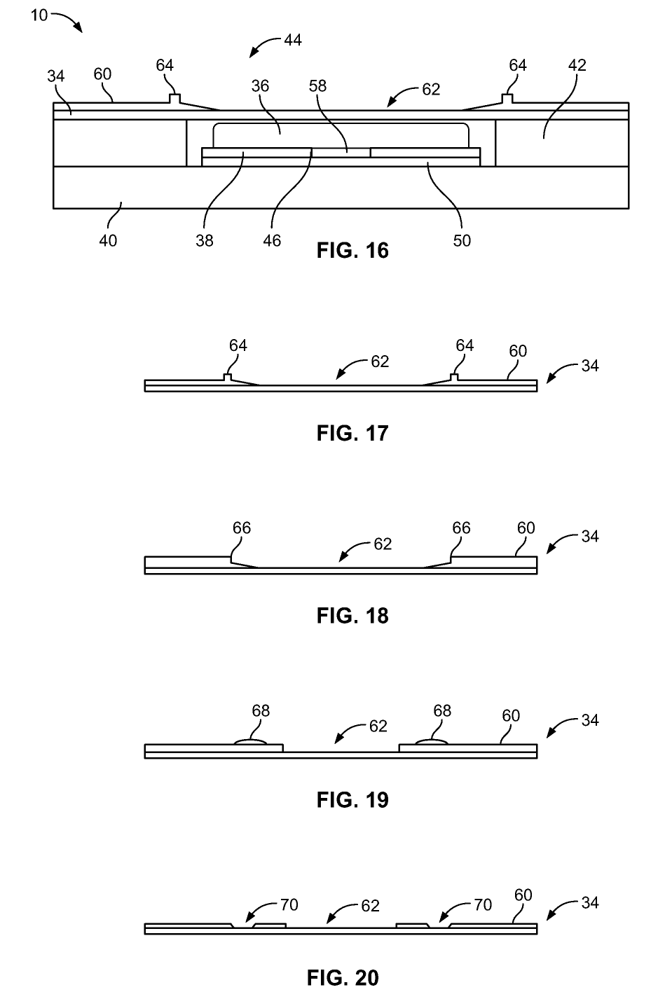

Further, elements of the sensor 110 may be integrated into the illuminated sensors illustrated above. For instance, the carrier sheet 113 may be the light guide 36 and the carrier sheet 114 the reaction surface 40 from FIG. 2. The carrier sheet 114 may also be the flat light layer 50 from FIGS. 4 and 16. The carrier sheet 113 may be the flat light layer 50 from FIG. 12. FIG. 11 shows the upper electrode 52 which may be analogized to electrode 115 of FIG. 30 and the lower electrode 54 to the electrode 116 of FIG. 30.

Now referring to FIG. 31, a graph 900 of the Resistance v. Force characteristics of the sensor 110 is shown. The resistance of the sensor 110 is shown on the Y-axis, and the force acting upon the sensor 110 is shown on the X-axis. At relatively low forces (e.g., at point 910 below approximately 1 N), the sensor 110 exhibits relatively high resistance characteristics (e.g., approximately 300 kilohms or higher) behaving substantially as an isolator. At relatively high forces (e.g., at point 920 above approximately 3 N), the sensor 110 exhibits relatively low resistance characteristics (e.g., approximately 1 kilohm or lower) approaching behaving substantially as a conductor. Between approximately 1 N and 3 N, the sensor 110 exhibits intermediate levels of resistance between approximately 3 kilohms and 1 kilohm that decreases in a predictable manner with increasing force.

The conductive or electrical characteristics of the sensor 110 (i.e., the Resistance v. Force characteristic curve 900) may configured according to the selection of different materials and providing different arrangements of the carrier sheets 113, 114, conductors 111, 112, electrodes 115, 116, and pressure sensitive material 117. For example, as described above, the conductive layers of the sensor 110 (i.e., the conductors 111, 112, electrode 115, 116, and pressure sensitive material 117) may be configured in different manners, such as with different materials and/or different thickness, to change the conductive or electrical characteristics of the sensor 110. The type of material may also be used to tune the characteristics of the sensor 110. For example, a particular QTC material be selected (e.g., a polymer, a conductor blend, etc.) to affect the conductive or electrical characteristics.

The carrier sheets 113, 114, may also be configured in different manners to change the conductive or electrical characteristics of the sensor 110. For example, the relative position of the carrier sheets 113, 114, may be adjusted. Referring to FIG. 30, the carrier sheets 113, 114 may be spaced apart in regions proximate the sensor 110 so as to provide a gap (as shown) between the pressure sensitive material 117 and the electrode 115. By providing a gap, a sufficient force must act upon the carrier sheets 113, 114 to deflect a corresponding distance before force acts upon the pressure sensitive material. Thus, referring to the graph of FIG. 31, the Resistance v. Force characteristics of the sensor 110 may be shifted rightward by a desired force offset (i.e., number of Newtons) by providing a gap of a certain size (e.g., 35 microns) corresponding to the spring rate of the carrier sheets 113, 114. The gap may, for example, be provided by an adhesive used to combine the carrier sheets 113, 114. According to another example, the sensor 110 may be preloaded to have the opposite effect of a gap, such as with an externally provided physical load, effectively shifting the Resistance v. Force characteristics of the sensor 110 leftward.

The conductive or electrical characteristics of the sensor 110 may also be changed according to the materials used for the carrier sheets 113, 114. A stiffer first or outer carrier sheet 113 may be provided, such as by utilizing a thicker material or a different material. By using a stiffer outer sheet 113, greater force must act upon the outer carrier sheet 113 to deflect a similar distance as compared to a less stiff material. Thus, referring to the graph of FIG. 31, the Resistance v. Force characteristics of the sensor 110 are elongated or extended (not shifted) rightward, such that for higher loads result, incremental changes of force result in larger changes of resistance to allow for more accurate detection by the controller or measuring device. The inner sheet 114 may also be configured to provide a stable base and may have a lower, same, or higher stiffness than the outer sheet 113.

While the sensors 110 have been described as being responsive to compressive loads, the sensors 110 are also responsive to bending loads that cause deflection of the carrier sheets 113, 114 and pressure sensitive material 117. Thus, for simple and/or reliable calibration, the pressure sensors 110 are maintained in a generally flat arrangement where measurements for compressive loads are desired. According to other examples, the sensors 110 may be utilized in applications where measurements for torsional loads are desired.

Aspects of the present invention are described above with reference to flowchart illustrations, schematics and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

Computer program code for carrying out operations for aspects of the present invention may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

A number of aspects of the systems, devices and methods have been described. Nevertheless, it will be understood that various modifications may be made without departing from the spirit and scope of the disclosure. Accordingly, other aspects are within the scope of the following claims.

What is claimed:

1. A human interface comprising:
a light emitter;
a pressure sensitive material having a composition configured to vary electrical properties of the pressure sensitive material in relation to an amount of pressure applied thereto, the light emitter coupled to the pressure sensitive material, wherein variation of the electrical properties of the pressure sensitive material causes variation of at least one illumination characteristic; and
a processor, wherein the processor is configured to determine a position of the amount of pressure applied to the pressure sensitive material based on the electrical properties of the pressure sensitive material, and wherein the electrical properties of the pressure sensitive material exhibit a characteristic curve.

2. The human interface of claim 1, wherein the light emitter includes a light emission spatial component having a commonality with a spatial component of the pressure sensitive material.

3. The human interface of claim 2, wherein the processor is configured determine the position of the amount of pressure relative to the spatial component of the pressure sensitive material and map the spatial component of the pressure sensitive material onto the light emission spatial component for variation of the at least one illumination characteristic.

4. The human interface of claim 3, wherein the commonality is a linear direction.

5. The human interface of claim 3, wherein the spatial component of the pressure sensitive material is subdivided into zones and the light emission spatial component is subdivided into zones.

6. The human interface of claim 5, wherein the processor is configured to map the amount of pressure on one of the zones of the spatial component of the pressure sensitive material onto a corresponding one of the zones of the light emission spatial component.

7. The human interface of claim 1, wherein the light emitter includes a spatial component, and wherein the processor is configured to cause the light emitter to increase illumination along the spatial component in proportion to the amount of pressure.

8. The human interface of claim 7, wherein the spatial component of the light emitter includes a plurality of zones extending in the direction of the spatial component.

9. The human interface of claim 1, wherein the pressure sensitive material includes a spatial component and wherein the at least one illumination characteristic is a graphical characteristic.

10. The human interface of claim 9, wherein the graphical characteristic is one of an alphanumeric sequence, and wherein the processor is configured to cause the alphanumeric sequence to increase or decrease in proportion to the amount of pressure applied to the pressure sensitive material.

11. The human interface of claim 1, wherein the pressure sensitive material is positioned on the light emitter.

12. The human interface of claim 11, wherein the pressure sensitive material is configured to at least partially allow passage of light from the light emitter therethrough so as to form the at least one illumination characteristic.

13. The human interface of claim 12, wherein the pressure sensitive material includes at least one opening configured to allow passage of light from the light emitter.

14. The human interface of claim 13, wherein the at least one opening is an array of openings.

15. The human interface of claim 14, wherein the processor is configured to determine when a proximal opening of the array of openings is in proximity to the position and to cause the light emitter to emit light through the proximal opening.

16. The human interface of claim 14, wherein the processor is configured to determine a path of the amount of pressure.

17. The human interface of claim 16, wherein the processor is configured to determine when proximal openings of the array of openings are in proximity to the path and to cause the light emitter to emit light through the proximal openings.

18. The human interface of claim 1, wherein the at least one illumination characteristic includes at least one of an intensity of illumination emitted by the light emitter, a visibility of light emitted from the light emitter, or a position of illumination on the human interface.

19. The human interface of claim 1, further comprising a cover sheet disposed above the light emitter and configured to deflect under normal finger pressure, the cover sheet defining at least one recessed portion on an external surface thereof, the recessed portion being disposed above a perimeter of a pressure sensing area defined by the pressure sensitive material, and an external surface of the human interface comprises the external surface of the cover sheet.

20. The human interface of claim 1, further comprising a light guide positioned on the pressure sensitive material.
